(19) United States
(12) Patent Application Publication
(10) Pub. No.: US 2007/0208162 A1
(43) Pub. Date: Sep. 6, 2007

(54) Electroluminescent Polymer and Organic Electroluminescent Device

(76) Inventors: Tomoyasu Sunaga, Tochigi (JP); Junichi Ishii, Tochigi (JP); Shingo Deguchi, Tochigi (JP)

Correspondence Address: OSHA LIANG L.L.P., 1221 MCKINNEY STREET, SUITE 2800, HOUSTON, TX, 77010, US

(21) Appl. No.: 10/589,147

(22) PCT Filed: Feb. 10, 2005
(86) PCT No.: PCT/JP05/02082

§ 371 Date: Jan. 25, 2007

(30) Foreign Application Priority Data
Feb. 12, 2004 (JP) 2004-034945

(51) Int. Cl. H01L 51/54; C09K 11/06

(52) U.S. Cl. 528/397; 428/690; 428/917; 313/504; 257/40; 257/E51.032; 528/394; 528/482

(57) ABSTRACT

The present invention relates to an electric transfer light emitting polymer that emits light by applying an electric field thereto. Chlorine (Cl) and the sum total (ΣM) of metal elements included in the polymer satisfies a relation of a below-described formula 1.
ΣM<Cl (1) (In this case, ΣM designates the sum total of metal elements composed of one kind or a plurality of kinds between alkali metal elements, alkali earth metal elements, elements in the third period showing no anionic characteristics, elements in the fourth period showing no anionic characteristics and elements in the fifth period showing no anionic characteristics.)

### TECHNICAL FIELD

The present invention relates to an electric transfer light emitting polymer that is excited to emit light by applying an electric field thereto and an organic electroluminescence element having the electric transfer light emitting polymer in a light emitting layer and used as a display element or a light emitting element.

This application claims a priority based on Japanese Patent Application No. 2004-034945 filed on Feb. 12, 2004 in Japan that is applied to this application with reference thereto.

### BACKGROUND ART

It has been hitherto widely known that when an electric field is applied to excite a fluorescent compound such as anthracene, the fluorescent compound emits light. As a display element or a light emitting element using the characteristics of such a fluorescent compound, an electroluminescence element (refer it to as an EL element, hereinafter) is exemplified. Since the EL element serves as the display element or the light emitting element having such self-light emitting characteristics as to emit light by applying the electric field thereto and a high visibility, various kinds of EL elements are studied and developed. Specifically, exemplified is an inorganic EL element using an inorganic material as a fluorescent material or an organic EL element using an organic material.

In the organic EL element of them, an electron and a hole (positive hole) are injected from an external part so that an organic fluorescent material is excited to emit light by a recombination energy when they are recombined together in a light emitting layer including the organic fluorescent material. This organic EL element has an advantage that the organic EL element can be driven by lower voltage than the inorganic EL element.

As the organic fluorescent material included in the light emitting layer, polymers for the EL element having various molecular structures are developed and various kinds of polymers for the EL element are proposed. The polymers for the EL element of this kind are disclosed in Japanese translation of PCT Patent Application No. 2001-527102 and Japanese Patent Application Laid-Open No. 2002-212977.

In such polymers for the EL element, impurities composed of, for instance, an inorganic element, specifically, a metal element such as sodium, nickel, palladium, or impurities such as chlorine may be mixed in a process for synthesizing a polymer.

Then, when the impurities such as the metal element are mixed in the polymer for the EL element used in the light emitting layer of the organic EL element, the impurities may possibly cause inconveniences that the impurities become, for instance, conditions of metal ions in the light emitting layer to serve to quench the light and lower a light emitting efficiency, or react with the polymer to deteriorate the polymer itself, shorten the life of the organic EL element, and further change a light emitting color.

Under the present condition, in the techniques disclosed in the above-described patent documents, kinds of the impurities that are mixed in the polymer for the EL element to cause inconveniences or the inconveniences caused by the mixed impurities when the polymer for the EL element is used in the light emitting layer of the organic EL element are not recognized nor reported.

### DISCLOSURE IF THE INVENTION

Problems to be Solved by the Invention

It is an object of the present invention to provide a new electric transfer light emitting polymer and an organic electroluminescence element using the electric transfer light emitting polymer that can solve the problems of the above-described usual polymer for the EL element and the organic EL element using the polymer for the EL element.

It is another object of the present invention to provide an electric transfer light emitting polymer capable of obtaining a light emitting layer in which the fall of a light emitting efficiency, the deterioration of a life and the change of a light emitting color can be suppressed and an organic electroluminescence element having the light emitting layer including the electric transfer light emitting polymer.

For achieving the above-described objects, the inventors found that when an electric transfer light emitting polymer was synthesized that emitted light by applying an electric field thereto, a material used for a synthesis or a synthesizing process was selected to restrict a quantity of chlorine mixed in the synthesized electric transfer light emitting polymer and a quantity of a mixed metal element that caused an inconvenience in the electric transfer light emitting polymer was reduced more than the quantity of chlorine whose mixed quantity is restricted to a small quantity, so that an organic electroluminescence element was obtained in which the fall of a light emitting efficiency, the deterioration of the life of an element and the change of a light emitting color were suppressed.

Specifically, an electric transfer light emitting polymer according to the present invention is such an electric transfer light emitting polymer as to emit light by applying an electric field thereto. Chlorine (Cl) and the sum total (ΣM) of metal elements included in the polymer satisfy a relation of a below-described formula 1.
ΣM<Cl (1)
(In this case, ΣM designates the sum total of metal elements composed of one kind or a plurality of kinds between alkali metal elements, alkali earth metal elements, elements in the third period showing no anionic characteristics, elements in the fourth period showing no anionic characteristics and elements in the fifth period showing no anionic characteristics.)

Further, an organic electroluminescence element according to the present invention is an element having on a substrate a first electrode layer, a light emitting layer having an electric transfer light emitting polymer that emits light by applying an electric field thereto and a second electrode layer in this order. Chlorine (Cl) and the sum total (ΣM) of metal elements included in the electric transfer light emitting polymer of the light emitting layer satisfy a relation of a below-described formula 2.
ΣM<Cl (2)
(In this case, ΣM designates the sum total of metal elements composed of one kind or a plurality of kinds between alkali metal elements, alkali earth metal elements, elements in the third period showing no anionic characteristics, elements in the fourth period showing no anionic characteristics and elements in the fifth period showing no anionic characteristics.)

According to the present invention, when the light emitting layer of the organic electroluminescence element is formed, the content of the metal element, specifically, nickel, sodium and palladium that may possibly cause an inconvenience in the light emitting layer is reduced more than a quantity of chlorine whose content relative to the electric transfer light emitting polymer forming the light emitting layer can be reduced.

Thus, according to the present invention, since the chlorine and metal element contents that cause an inconvenience in the light emitting layer can be greatly reduced relative to the electric transfer light emitting polymer, the organic electroluminescence element can be obtained in which the generation of the inconvenience by impurities is suppressed.

According to the present invention, the metal element content in the electric transfer light emitting polymer that causes the inconvenience in the light emitting layer is reduced more than the chlorine content in the electric transfer light emitting polymer forming the light emitting layer of the organic electroluminescence element, so that the quantity of impurities included in the polymer can be decreased.

Thus, according to the present invention, since the quantity of the impurities included in the electric transfer light emitting polymer that cause the inconvenience in the light emitting layer can be extremely reduced, the organic electroluminescence element can be obtained in which inconveniences such as the decrease of a light emitting efficiency, the deterioration of the life of an element and the change of a light emitting color can be suppressed.

Still another object of the present invention and advantages obtained by the present invention will be more apparent from an embodiment described below by referring to the drawings.

### BRIEF DESCRIPTION OF THE DRAWING

FIG. 1 is a sectional view schematically showing the structure of an organic electroluminescence element to which the present invention is applied.

### BEST MODE FOR CARRYING OUT THE INVENTION

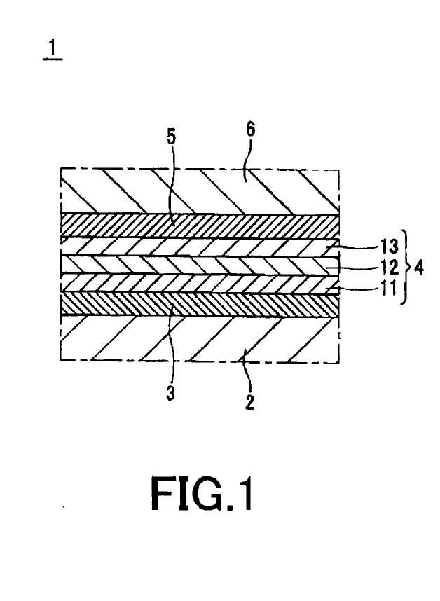

Now, referring to the drawings, an electric transfer light emitting polymer and an organic electroluminescence element (refer it to as an organic EL element, hereinafter.) according to the present invention will be described below. The organic EL element 1 shown in FIG. 1 includes a transparent substrate 2, a first electrode layer 3 as an anode formed on the transparent substrate 2, an organic electroluminescence layer (refer it to as an organic EL layer) 4 formed on the first electrode layer 3, a second electrode layer 5 as a cathode formed on the organic EL layer 4, and a protecting layer 6 formed on the second electrode layer 5.

As the transparent substrate 2, any substrate having, for instance, a light transmittance and insulating characteristics may be employed. Specifically, a plastic film or sheet, for instance, polyethylene terephthalate, polyethylene naphthalate, polypropylene, polyether sulfone, polycarbonate, cycloolefin polymer, polyallylate, polyamide, polymethyl methacrylate, etc. or an inorganic substrate such as glass or quartz may be used. On the transparent substrate 2, a transparent barrier film or a transparent barrier film made of an inorganic thin film may be laminated as required. Further, in the transparent substrate 2, for instance, a layer having a light scattering effect may be formed on its main surface. Further, when the transparent substrate 2 is formed with a plastic, light scattering particles may be included in the above-described plastic resin to provide the light scattering effect.

As the first electrode layer 3 serving as the anode, a material is used that has a large work function of an electrode material from a vacuum level to efficiently inject a positive hole (refer it to as a hole, hereinafter.) to the below-described organic EL layer 4 and a light transmittance to take out light emitted from a below-described light emitting layer 12 from the anode side. Specifically, for instance, ITO, SnO₂, ZnO, etc. may be exemplified. Especially, ITO (Indium Tin Oxide) may be preferably employed from the viewpoints of productivity and controllability.

As a method for forming the first electrode layer 3, a dry film forming method such as a resistance heating deposition method, an electron beam deposition method, a reactive deposition method, an ion plating method, a sputtering method, etc. or a wet film forming method such as a gravure printing method, a screen printing method, etc. may be employed.

A surface treatment, for instance, a corona discharge process, a plasma process, a UV ozone process, etc. is previously applied to the main surface of the transparent substrate 2, so that an adhesion between the transparent substrate 2 and the first electrode layer 3 can be improved.

The first electrode layer 3 preferably has a thickness located within a range of 10 μm or less. When the thickness of the first electrode layer 3 is larger than 10 μm, the light transmittance of the light emitted by the below-described light emitting layer 12 is deteriorated, and accordingly, the first electrode layer 3 is not suitable for a practical use.

The organic EL layer 4 has a hole transport layer 11, the light emitting layer 12 and an electron transport layer 13. These layers are respectively laminated in this order on the first electrode layer 3 serving as the anode. Before the organic EL layer 4 is laminated on the first electrode layer 3, a surface treatment, for instance, the corona discharge process, the plasma process, the UV ozone process, a laser irradiation process, etc. is preferably performed for the purpose of cleaning or reforming the surface of the first electrode layer 3.

The hole transport layer 11 transports the hole injected from the first electrode layer 3 as the anode to the light emitting layer 12. For the hole transport layer 11, may be exemplified, for instance, benzine, styryl amine, triphenyl methane, porphyrin, triazole, imidazole, oxadiazole, polyaryl alkane, phenylene diamine, aryl amine, oxazole, anthracene, fluorene, hydrazone, stilbene or derivatives of them and heterocyclic conjugated monomers, oligomers and polymers such as polysilane compounds, vinyl carbazole compounds, thiophene compounds, aniline compounds, etc., and one kind or a plurality of kinds of them are mixed together and a mixture is employed.

Specifically, naphthyl phenylene diamine, porphyrin, metal tetraphenyl porphyrin, metal naphthalocyanine, 4,4′,4″-trimethyl triphenyl amine, 4,4′,4″-tris (3-methyl phenyl phenyl amino) triphenyl amine, N,N,N′,N′-tetrakis (p-tolyl) p-phenylene diamine, N,N,N′,N′-tetraphenyl 4,4′-diaminobiphenyl, N-phenyl carbazole, 4-di-p-tolyl amino stilbene, poly (paraphenylene vinylene), poly (thiophene vinylene), poly (2,2′-thienyl pyrrole), etc. may be exemplified, however, the material of the hole transport layer is not limited thereto.

In the light emitting layer 12, an electron is combined with the hole and the energy thereof is radiated as the light. For the light emitting layer 12, for instance, an organic material, for instance, a low molecular fluorescent dye, a fluorescent polymer, a metallic complex or the like is employed hat has characteristics that when voltage is applied, the hole can be injected from the first electrode layer 3 side and the electron can be injected from the below-described second electrode layer 5 side, the injected electric charge, that is, the hole and the electron can be moved to provide a place where the hole is recombined with the electron and a light emitting efficiency due to its energy is high. Namely, an electric transfer light emitting polymer is used that emits light by applying an electric field thereto. As such an electric transfer light emitting polymer, for instance, a fluorene copolymer may be exemplified that has a chemical structure shown by a below-described chemical formula 1 as a structural unit and a polymer having one or more units of the fluorene copolymer is used. In the fluorene copolymer shown in the chemical formula 1, to carbons on a benzene ring, for instance, hydrogen elements or alkyl groups are introduced.

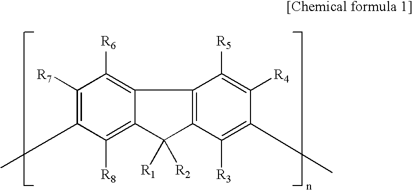

In the chemical formula 1, n indicates a value not smaller than 1. To R₁ and R₂, any one kind or a plurality of kinds of a hydrogen atom, an alkyl group, an alkenyl group, an alkynyl group, an aralkyl group, an aryl group, a hetero aryl group, an alkoxy group, an aryloxy group and an aliphatic hetero group are introduced. To R₃ to R₈, a hydrogen atom or an alkyl group is introduced.

Specifically, as the fluorene copolymer, are exemplified, for instance, poly (9,9-dioctyl) fluorene shown by a below-described chemical formula 2, poly (9,9-diethyl hexyl) fluorene shown by a below-described chemical formula 3, poly (9,9-diethyl hexyl) fluorene having a terminal end capped that is shown by a below-described chemical formula 4. These copolymers are individually used or mixed together and used.

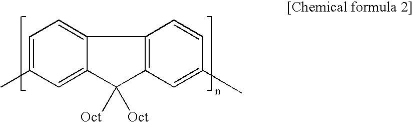

(In this case, n indicates a value not smaller than 1) 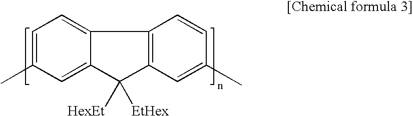
(In this case, n is a value not smaller than 1, and EtHex represents below-described formula.) 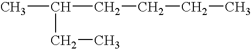 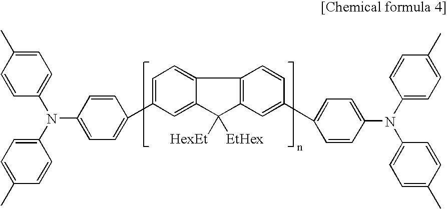
(In this case, n is a value not smaller than 1 and EtHex represents below-described formula.)

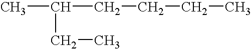

In addition to these fluorene copolymers, may be used polymer materials such as anthracene, naphthalene, phenanthrene, pyrene, chrysene, perylene, butadiene, coumarin, acridine, stilbene, tris(8-quinolinolato) aluminium complex, bis(benzoquinolinolato) beryllium complex, tri(dibenzoyl methyl) phenanthroline europium complex, ditolyl vinyl biphenyl, etc. or existing light emitting materials or the like.

Then, in the electric transfer light emitting polymer forming the light emitting layer 12, a material used for synthesizing the polymer when the light emitting layer 12 is formed or a process for a synthesis is selected, so that the sum total of the content of impurities such as metal elements, for instance, nickel, sodium and palladium that may possibly cause an inconvenience in the polymer is reduced more than the content of chlorine whose mixing can be suppressed to a small quantity. That is, in the electric transfer light emitting polymer, the chlorine content (Cl) in the polymer and the sum total (ΣM) of the content of metal elements as impurities in the polymer satisfy a relation formula of ΣM<Cl.

Specifically, in the electric transfer light emitting polymer, when the polymer is synthesized, as the material used for the synthesis, a material including little chlorine as much as possible is used and the synthesis is carried out by a method with which chlorine is not associated in a synthesizing process. Thus, the quantity of chlorine included in the polymer can be reduced as much as possible. Then, the impurity content that causes an inconvenience in the polymer is more reduced than chlorine whose content in the polymer is set to a slight quality. As a factor that chlorine is mixed in the electric transfer light emitting polymer synthesized by suppressing the chlorine content to a small quantity as described above, for instance, chloride in atmospheric air and chloride previously included in the material as impurities may be considered.

In such a way, since the impurity content that causes the inconvenience in the polymer is more reduced than chlorine whose content is a small quantity, a disadvantage caused in the light emitting layer 12 can be suppressed.

Further, in the electric transfer light emitting polymer, since chlorine is also impurities that deteriorate the light emitting characteristics of the organic EL element 1, as the chlorine content in the polymer becomes lower, an effect for restraining the deterioration of the light emitting characteristics generated in the light emitting layer 12 can be more increased. Specifically, the quantity of chlorine included in the electric transfer light emitting polymer is less than 200 ppm, preferably less than 100 ppm and more preferably not more than 50 ppm.

As a method for removing the impurities in the electric transfer light emitting polymer, various methods may be considered. For instance, there is a method in which the synthesized electric transfer light emitting polymer is temporarily dispersed in an organic solvent, further, aqueous solution including a chelating agent is added thereto to carry metal elements such as nickel, sodium, palladium as the impurities in the polymer by the chelating agent, and then, the aqueous solution including the chelating agent carrying the impurities is removed. In such a way, the quantity of the impurities in the polymer can be decreased.

As the chelating agent used herein, for instance, ethylene diamine tetraacetic acid (refer it to as EDTA, hereinafter.), salts of EDTA, etc. may be exemplified. Specifically, disodium salt (EDTA/2Na) or diammonium salt (EDTA/2NH₄) of EDTA or the like is employed.

Here, the method for removing the impurities in the polymer by using the chelating agent is described as an example. However, a material used for a synthesis or a synthesizing method is selected so that the quantity of the impurities can be decreased as in the case of reducing the chlorine content.

The electron transport layer 13 in the organic EL layer 4 transports an electron injected from the below-described second electrode layer 5 to the light emitting layer 12. For the electron transport layer 13, for instance, quinoline, perylene, bisstyryl, pyrazine or derivatives of them may be exemplified, and one kind or a plurality of kinds of them are mixed together and used.

Specifically, for instance, 8-hydroxy quinoline aluminum, anthracene, naphthalene, phenanthrene, pyrene, chrysene, perylene, butadiene, coumarin, acridine, stilbene or the derivatives of them may be exemplified, however, the material of the electron transport layer is not limited thereto.

The organic EL layer 4 having such a structure is obtained by sequentially laminating and forming the layers 11, 12 and 13 respectively by using, for instance, a vapor deposition method such as a resistance heating method, an electron beam method, etc., a coating method such as a spin coat, a spray coat, a flexographic method, a gravure method, a roll coat, an intaglio offset method, etc. or an ink jet printing method. Further, the entire thickness of the organic EL layer 4 is set to 1000 nm or less and preferably to 50 to 150 nm.

In the above description, the organic EL layer 4 having the structure that the light emitting layer 12 is independent is explained, however, the organic EL layer 4 is not limited to the above-described structure. For instance, a hole transport and light emitting layer serving as the hole transport layer 11 and the light emitting layer 12 or an electron transport and light emitting layer serving as the electron transport layer 13 and the light emitting layer 12 can be used. When the hole transport and light emitting layer is used, since the hole injected to the hole transport and light emitting layer from the anode is closed by the electron transport layer, a recombination efficiency is improved. Further, when the electron transport and light emitting layer is used, since the electron injected to the electron transport and light emitting layer from the cathode is closed by the electron transport and light emitting layer, the recombination efficiency is improved as in the case of using the hole transport and light emitting layer.

For the second electrode layer 5 as the cathode, to efficiently inject the electron to the organic EL layer 4, metal is used that has a small work function of an electrode material from a vacuum level. Specifically, may be exemplified metals having the small work function, for instance, aluminum, indium, magnesium, silver, calcium, barium, lithium, etc. and alloys are formed by using one kind or a plurality of kinds of them and used. Further, alloys may be formed by using these metals together with other metals to enhance a stability and used.

As a method for forming the second electrode layer 5, may be employed, for instance, a resistance heating deposition method, an electron beam deposition method, a reactive deposition method, an ion plating method, a sputtering method, a laminating method, etc. The thickness of the cathode is desirably 10 nm to 1000 nm.

The protecting layer 6 serves to seal the organic EL element 1 and cut off oxygen or water relative to the layers 3, 4 and 5, respectively to ensure the reliability of the driving of the organic EL element 1 and prevent the deterioration of the organic EL element 1. For the protecting layer 6, may be exemplified, for instance, aluminum, gold, chromium, niobium, tantalum, titanium, silicon oxide, silicon nitride, etc. and any one kind or a plurality of kinds of them are used.

In the organic EL element 1 constructed as described above, when the light emitting layer 12 of the organic EL layer 4 is formed, the content of the metal element, specifically, nickel, sodium and palladium that may possibly cause an inconvenience in the light emitting layer 12 is reduced more than a quantity of chlorine whose content relative to the electric transfer light emitting polymer forming the light emitting layer 12 is suppressed to a small quantity.

Thus, in the organic EL element 1, since the quantity of nickel, sodium and palladium that cause the inconvenience in the light emitting layer 12 including the electric transfer light emitting polymer is extremely reduced, inconveniences can be suppressed, such as the decrease of a light emitting efficiency, the deterioration of the life of an element and the change of a light emitting color that are caused by the metal elements such as nickel, sodium and palladium, etc. included in the light emitting layer 12.

Further, in the organic EL element 1, the material used for a synthesis or the synthesizing method is selected when the electric transfer light emitting polymer is synthesized so that the quantity of chlorine included in the polymer can be reduced. Accordingly, the inconveniences caused in the light emitting layer 12 can be more restricted.

The organic EL element 1 may have a laminated structure in which the layers 3, 5, 6, 11, 12 and 13 are respectively composed of a plurality of layers. Further, the above-described organic EL element 1 is not only directly used as a light emitting element or a display element of a thin display, but also may be used as, for instance, a back-light of a liquid crystal display, a light source for lighting, an indicator, etc.

Now, an explanation will be given to samples obtained by actually producing the organic EL element to which the present invention is applied.

<Sample 1>

In a sample 1, as the electric transfer light emitting polymer included in the light emitting layer, poly (9,9-dioctyl) fluorene was firstly synthesized. When this polymer was synthesized, bis (1,5-cyclooctadiene) nickel (describe it as Ni(COD)₂, hereinafter.) of 20 g (72.8 mmol), 2,2′-bipyridine of 11.4 g (72.8 mmol), N,N-dimethyl formamide of 60 ml, toluene of 160 ml were mixed together and the mixture was heated at 80° C. under an atmosphere of nitrogen. Then, after 5 minutes when the temperature reached 80° C., 1,5-cyclooctadiene of 5.6 ml (45.6 mmol) was added. Further, after 25 minutes, toluene solution including 2,7-dibromo-9,9-dioctyl fluorene of 17.3 g (31.6 mmol) was added and the solution was held at 80° C. and agitated. After 70 hours passed under this state, concentrated 35% hydrochloric acid of 20 ml was added to the solution and the solution was quenched. That is, a synthesizing reaction was stopped. In such a way, poly (9,9-dioctyl) fluorene having high viscosity was synthesized.

Then, impurities included in the poly (9,9-dioctyl) fluorene obtained in such a way were removed. When the impurities included in the polymer were removed, the poly (9,9-dioctyl) fluorene of 80 ml obtained as described above, tetrahydrofuran of 200 ml, toluene of 100 ml and 1N acetic acid aqueous solution of 100 ml were mixed together and violently agitated, then, the mixture was separated into an organic layer and a water layer and the water layer was removed. Then, after 5 wt % aqueous solution of diammonium salt of EDTA (EDTA/2NH₄) of 150 ml as a chelating agent was added to the organic layer and violently agitated, the water layer was removed. Then, after ion exchange water of 100 ml was added to the organic layer and violently agitated, the water layer was removed. The organic layer was concentrated to 30 ml by an evaporator. Then, the concentrated organic layer was introduced to a mixed solvent in which equal quantities of acetone and ethanol were mixed to independently separate and then filter the poly (9,9-dioctyl) fluorene and only the poly (9,9-dioctyl) fluorene was taken out and dried for 12 hours under pressure reduced. In such a way, the impurities included in the poly (9,9-dioctyl) fluorene were removed.

Subsequently, the organic EL element having the light emitting layer in which the poly (9,9-dioctyl) fluorene obtained as described above was included as the electric transfer light emitting polymer was produced. When the organic EL element was produced, a glass substrate having an ITO (indium-tin oxide: thickness of 200 nm, sheet resistance of 10 Ω/sq or lower, transmittance of 80% or more) film as an anode was firstly ultrasonic cleaned, then, rinsed by deionized water, then ultrasonic cleaned by isopropyl alcohol (describe it as IPA, hereinafter) and further boiled and cleaned by the IPA.

Then, a surface treatment was carried out in which the ITO film of the glass substrate to which a defatting process was applied as described above was irradiated with eximer UV light for several minutes to form the hole transport layer on the ITO film to which the surface treatment was performed. The hole transport layer was formed on the ITO film in such a way that BaytronP TP A1 4083 produced by Bayer was used for a hole transport polymer as a material and polymer solution including the hole transport polymer was applied on the ITO film by a spin coater so as to have the thickness of 30 nm after drying the solution and dried at 100° C. for one hour under reduced pressure.

Then, 1 wt % toluene solution of the above-described poly (9,9-dioctyl) fluorene was prepared. The polymer solution was filtered by a filter of polytetrafluoro ethylene having the diameter of a mesh of 0.2 μm. After that, the polymer solution was applied on the hole transport polymer by the spin coater so as to have the thickness of 70 nm after drying the polymer solution, and dried to form the light emitting layer on the hole transport polymer layer.

Then, on the light emitting layer, a cathode layer as a cathode was formed in such a way that calcium was deposited so as to have the thickness of 20 nm and aluminum was deposited so as to have the thickness of 150 nm under vacuum (3×10⁻⁴ Pa or lower) and they are sequentially laminated. In such a manner, the organic EL element was formed that uses the poly (9,9-dioctyl) fluorene as the electric transfer light emitting polymer forming the light emitting layer.

<Sample 2>

In a sample 2, a process for removing the impurities in the polymer was carried out in the same manner as that of the above-described sample 1 except that when the impurities included in the poly (9,9-dioctyl) fluorene synthesized in the same manner as that of the sample 1 were removed, 1N hydrochloric acid aqueous solution was used in place of the 1N acetic acid aqueous solution. Then, the organic EL element was formed in the same manner as that of the sample 1 except that the poly (9,9-dioctyl) fluorene in which the impurities in the polymer were removed as described above was used.

<Sample 3>

In a sample 3, a process for removing the impurities in the polymer was carried out in the same manner as that of the above-described sample 1 except that when the impurities included in the poly (9,9-dioctyl) fluorene synthesized in the same manner as that of the sample 1 were removed, disodium salt of EDTA (EDTA/2Na) was used in place of the 5 wt % aqueous solution of EDTA/2NH₄ as the chelating agent. Then, the organic EL element was formed in the same manner as that of the sample 1 except that the poly (9,9-dioctyl) fluorene in which the impurities in the polymer were removed as described above was used.

<Sample 4>

In a sample 4, a process for removing the impurities in the polymer was carried out in the same manner as that of the above-described sample 2 except that when the impurities included in the poly (9,9-dioctyl) fluorene synthesized in the same manner as that of the sample 1 were removed, tetrasodium salt of EDTA (EDTA/4Na) was used as the chelating agent. Then, the organic EL element was formed in the same manner as that of the sample 1 except that the poly (9,9-dioctyl) fluorene in which the impurities in the polymer were removed as described above was used.

<Sample 5>

In a sample 5, a process for removing the impurities in the polymer was carried out in the same manner as that of the above-described sample 4 except that when the impurities included in the poly (9,9-dioctyl) fluorene synthesized in the same manner as that of the sample 1 were removed, a process was initially added for spurting out hydrogen chloride gas to an organic layer obtained by mixing the poly (9,9-dioctyl) fluorene of 80 ml, tetrahydrofuran of 200 ml and toluene of 100 ml to dissolve chorine into the organic layer. Then, the organic EL element was formed in the same manner as that of the sample 1 except that the poly (9,9-dioctyl) fluorene in which the impurities in the polymer were removed as described above was used.

<Sample 6>

In a sample 6, a process for removing the impurities in the polymer was carried out in the same manner as that of the above-described sample 1 except that when the impurities included in the poly (9,9-dioctyl) fluorene synthesized in the same manner as that of the sample 1 were removed, distilled water was used in place of the 1N acetic aqueous solution and the chelating agent was not used, that is, the removal of the impurities by the chelating agent was not carried out. Then, the organic EL element was formed in the same manner as that of the sample 1 except that the poly (9,9-dioctyl) fluorene in which the impurities in the polymer were removed as described above was used.

Subsequently, the quantitative analysis of the impurities, specifically, sodium, nickel and chlorine was carried out to the poly (9,9-dioctyl) fluorene that forms the light emitting layers of the sample 1 to 6. Further, a maximum current efficiency of each sample was measured.

The quantitative analysis of sodium and nickel was carried out by an Inductively Coupled Plasma-Atomic Emission Spectroscopy (ICP-AES) method or an Inductively Coupled Plasma-Mass Spectroscopy (ICP-MS). Further, the quantitative analysis of chlorine was carried out by an ion chromatography method.

The measured results of impurity contents and maximum current efficiency of the samples are respectively shown below in table 1.

TABLE 1

| | | impurities in | | | maximum |
|---|---|---|---|---|---|
| | | polymer | | | current |
| | chelating | (ppm) | | | efficiency |
| | agent | Na | Ni | Cl | (cd/A) |
| Sample 1 | EDTA/2NH₄ | 1 | 1 | 20 | 0.77 |
| Sample 2 | EDTA/2NH₄ | 8 | 5 | 40 | 0.6 |
| Sample 3 | EDTA/2Na | 10 | 5 | 30 | 0.65 |
| Sample 4 | EDTA/4Na | 30 | 10 | 40 | 0.31 |
| Sample 5 | EDTA/4Na | 45 | 10 | 220 | 0.22 |
| Sample 6 | — | 35 | 40 | 60 | 0.33 |

In the table 1, the maximum current efficiency indicates a luminance (cd) per current (A), that is, efficiency of converting the current applied to the organic EL element to light. A larger numeric value shows a higher light emitting efficiency. In the samples 1 to 6, the maximum current efficiency was measured when voltage of 6.5 V was applied to the organic EL element.

As shown in the table 1, it is found that in the samples 1 to 3 in which the chlorine content is 40 ppm or less and the sum total of the contents of sodium and nickel is less than the chlorine content, the maximum current efficiency is higher than that of the samples 4 and 6 in which the sum total of the contents of sodium and nickel is not less than the chlorine content and the sample 5 having high chlorine content as much as 220 ppm.

In the samples 4 and 6, since the sum total of sodium and nickel included in the poly (9,9-dioctyl) fluorene forming the light emitting layer is not less than the chlorine content and the quantity of metal as the impurities is large, the light emitting efficiency is lowered to decrease the maximum current efficiency.

In the sample 5, since the quantity of chlorine included in the poly (9,9-dioctyl) fluorene forming the light emitting layer is too large, the light emitting layer is deteriorated by chlorine to lower the light emitting efficiency. Further, in the sample 5, since the metal content as the impurities is more than that of the samples 1 to 3, the maximum current efficiency is more decreased.

Especially, in the samples 4 and 5, since EDTA/4Na is used as the chelating agent, a quantity of mixing of Na in the polymer is increased so that the light emitting efficiency is greatly lowered due to Na to decrease the maximum current efficiency.

As compared with these samples, in the samples 1 to 3, when the poly (9,9dioctyl) fluorene is synthesized, the quantity of chlorine included in the polymer is suppressed to a small quantity and impurities (sodium, nickel) of a quantity smaller than the quantity of chlorine that is suppressed to the small quantity are merely included, so that the quantity of chlorine or the impurities included in the light emitting layer can be restricted to enhance the light emitting efficiency and increase the maximum current efficiency.

As apparent from the above description, it is very important in producing the organic EL element excellent in its maximum current efficiency to reduce the quantity of chlorine included in the poly (9,9-dioctyl) fluorene forming the light emitting layer and more reduce the sum total of sodium and nickel included in the polymer than the quantity of chlorine that is set to a small value.

Subsequently, samples 7 to 12 obtained by actually forming the organic EL element using poly (9,9diethylhexyl) fluorene as the electric transfer light emitting polymer included in the light emitting layer will be described below.

<Sample 7>

In a sample 7, as the electric transfer light emitting polymer included in the light emitting layer, poly (9,9-diethylhexyl) fluorene was synthesized. When this polymer was synthesized, Ni(COD)₂ of 20 g (72.8 mmol), 2,2′-bipyridine of 11.4 g (72.8 mmol), N,N-dimethyl formamide of 60 ml, and toluene of 160 ml were mixed together and the mixture was heated at 80° C. under an atmosphere of nitrogen. Then, after 5 minutes when the temperature reached 80° C., 1,5-cyclooctadiene of 5.6 ml (45.6 mmol) was added. Further, after 25 minutes, toluene solution including 2,7-dibromo-9,9-diethylhexyl fluorene of 17.3 g (31.6 mmol) was added and the solution was held at 80° C. and agitated. After 70 hours passed under this state, concentrated 35% hydrochloric acid of 20 ml was added to the solution and the solution was quenched. In such a way, poly (9,9-diethylhexyl) fluorene having high viscosity was synthesized.

Then, in the sample 7, impurities in the polymer were removed in the same manner as that of the sample 1 for the poly (9,9-diethylhexyl) fluorene obtained as described above. Then, the organic EL element was produced in the same manner as that of the sample 1 except that the poly (9,9-diethylhexyl) fluorene in which the impurities in the polymer were removed in such a way was used.

<Sample 8>

In a sample 8, the organic EL element was produced in the same manner as that of the sample 2 except that the poly (9,9-diethylhexyl) fluorene was used as the electric transfer light emitting polymer.

<Sample 9>

In a sample 9, the organic EL element was produced in the same manner as that of the sample 3 except that the poly (9,9-diethylhexyl) fluorene was used as the electric transfer light emitting polymer.

<Sample 10>

In a sample 10, the organic EL element was produced in the same manner as that of the sample 4 except that the poly (9,9-diethylhexyl) fluorene was used as the electric transfer light emitting polymer.

<Sample 11>

In a sample 11, the organic EL element was produced in the same manner as that of the sample 5 except that the poly (9,9-diethylhexyl) fluorene was used as the electric transfer light emitting polymer.

<Sample 12>

In a sample 12, the organic EL element was produced in the same manner as that of the sample 6 except that the poly (9,9-diethylhexyl) fluorene was used as the electric transfer light emitting polymer.

Subsequently, the quantitative analysis of sodium, nickel and chlorine was carried out to the poly (9,9-diethylhexyl) fluorene that forms the light emitting layers of the samples 7 to 12. Further, a maximum current efficiency of each sample was measured. The quantitative analysis of sodium, nickel and chlorine was carried out in the same methods as those of the samples 1 to 6.

The measured results of impurity contents and maximum current efficiency of the samples are respectively shown below in table 2.

In the table 2, the maximum current efficiency indicates that a larger numeric value shows a higher light emitting efficiency like the table 1. In the samples 7 to 12, the maximum current efficiency was measured when voltage of 6 V was applied to the organic EL element.

TABLE 2

| | | impurities in | | | maximum |
|---|---|---|---|---|---|
| | | polymer | | | current |
| | chelating | (ppm) | | | efficiency |
| | agent | Na | Ni | Cl | (cd/A) |
| Sample 7 | EDTA/2NH₄ | 1 | 1 | 10 | 0.25 |
| Sample 8 | EDTA/2NH₄ | 10 | 10 | 40 | 0.1 |
| Sample 9 | EDTA/2Na | 15 | 3 | 40 | 0.1 |
| Sample 10 | EDTA/4Na | 30 | 20 | 45 | 0.01 |
| Sample 11 | EDTA/4Na | 60 | 15 | 200 | 0.01 |
| Sample 12 | — | 25 | 50 | 65 | 0.01 |

As shown in the table 2, it is found that in the samples 7 to 9 in which the chlorine content is 50 ppm or less and the sum total of the contents of sodium and nickel is less than the chlorine content, the maximum current efficiency is higher than that of the samples 10 and 12 in which the sum total of the contents of sodium and nickel is not less than the chlorine content and the sample 11 having high chlorine content as much as 200 ppm.

In the samples 10 and 12, since the quantity of sodium and nickel as the impurities included in the poly (9,9-diethylhexyl) fluorene forming the light emitting layer is large like the above-described sample 4, the light emitting efficiency is lowered to decrease the maximum current efficiency.

In the sample 11, since the quantity of chlorine included in the poly (9,9-diethylhexyl) fluorene forming the light emitting layer is too large like the above-described sample 5, the light emitting efficiency is deteriorated to decrease the maximum current efficiency. Further, in the sample 11, since the metal content as the impurities is more than that of the samples 7 to 9, the maximum current efficiency is more decreased.

Especially, in the samples 10 and 11, since EDTA/4Na is used as the chelating agent, a quantity of mixing of Na in the polymer is increased so that the light emitting efficiency is greatly lowered due to Na to decrease the maximum current efficiency.

As compared with these samples, in the samples 7 to 9, the quantity of the impurities such as chlorine or the metal elements included in the poly (9,9-diethylhexyl) fluorene is small like the above-described samples 1 to 3, the light emitting efficiency is enhanced so that the maximum current efficiency can be increased.

In the samples 7 to 12 using the poly (9,9-diethylhexyl) fluorene for the light emitting layer, the maximum current efficiency is generally more decreased than that of the samples 1 to 6 using the poly (9,9-dioctyl) fluorene for the light emitting layer. Since the value of visibility is included in the luminance (cd), the color of light emitted by the light emitting layer needs to be considered. That is, a phenomenon that a difference arises in the maximum current efficiency depending on the kinds of the polymers forming the light emitting layer may be considered to be greatly due to an influence from the difference between the light emitting colors. Specifically, the samples 1 to 6 using the poly (9,9-dioctyl) fluorene for the light emitting layer emit the light of green and the samples 7 to 12 using the poly (9,9-diethylhexyl) fluorene for the light emitting layer emit the light of light blue.

As apparent from the above description, it is very important in producing the organic EL element excellent in its maximum current efficiency to reduce the quantity of chlorine included in the poly (9,9-diethylhexyl) fluorene forming the light emitting layer and more reduce the sum total of sodium and nickel included in the polymer than the quantity of chlorine that is set to a small value.

Subsequently, samples 13 to 18 obtained by actually forming the organic EL element using poly (9,9-diethylhexyl) fluorene having a terminal end capped by di(p-tolyl)-4-bromophenyl amine as the electric transfer light emitting polymer included in the light emitting layer will be described below.

<Sample 13>

In a sample 13, as the electric transfer light emitting polymer included in the light emitting layer, poly (9,9-diethylhexyl) fluorene having an end capped by di(p-tolyl)-4-bromophenyl amine was synthesized. When this polymer was synthesized, Ni(COD)₂ of 20 g (72.8 mmol), 2,2′-bipyridine of 11.4 g (72.8 mmol), N,N-dimethyl formamide of 60 ml, and toluene of 160 ml were mixed together and the mixture was heated at 80° C. under an atmosphere of nitrogen. Then, after 5 minutes when the temperature reached 80° C., 1,5-cyclooctadiene of 5.6 ml (45.6 mmol) was added. Further, after 25 minutes, toluene solution including 2,7-dibromo-9,9-diethylhexyl fluorene of 16.6 g (30.3 mmol) and di(p-tolyl)-4-bromophenyl amine of 448 mg (1.28 mmol) was added and the solution was held at 80° C. and agitated. After 70 hours passed under this state, concentrated 35% hydrochloric acid of 20 ml was added to the solution and the solution was quenched. In such a way, poly (9,9-diethylhexyl) fluorene having a terminal end capped by di(p-tolyl)-4-bromophenyl amine with high viscosity was synthesized.

Then, in the sample 13, impurities in the polymer were removed in the same manner as that of the sample 1 for the poly (9,9-diethylhexyl) fluorene having a terminal end capped obtained as described above. Then, the organic EL element was produced in the same manner as that of the sample 1 except that the poly (9,9-diethylhexyl) fluorene having a terminal end capped in which the impurities in the polymer were removed in such a way was used.

<Sample 14>

In a sample 14, the organic EL element was produced in the same manner as that of the sample 2 except that the poly (9,9-diethylhexyl) fluorene having a terminal end capped was used as the electric transfer light emitting polymer.

<Sample 15>

In a sample 15, the organic EL element was produced in the same manner as that of the sample 3 except that the poly (9,9-diethylhexyl) fluorene having a terminal end capped was used as the electric transfer light emitting polymer.

<Sample 16>

In a sample 16, the organic EL element was produced in the same manner as that of the sample 4 except that the poly (9,9-diethylhexyl) fluorene having a terminal end capped was used as the electric transfer light emitting polymer.

<Sample 17>

In a sample 17, the organic EL element was produced in the same manner as that of the sample 5 except that the poly (9,9-diethylhexyl) fluorene having a terminal end capped was used as the electric transfer light emitting polymer.

<Sample 18>

In a sample 18, the organic EL element was produced in the same manner as that of the sample 6 except that the poly (9,9-diethylhexyl) fluorene having a terminal end capped was used as the electric transfer light emitting polymer.

Subsequently, the quantitative analysis of sodium, nickel and chlorine was carried out to the poly (9,9-diethylhexyl) fluorene having a terminal end capped that forms the light emitting layers of the samples 13 to 18. Further, a maximum current efficiency and a time in which the luminance is damped to 80% in each sample were measured. The quantitative analysis of sodium, nickel and chlorine was carried out in the same methods as those of the samples 1 to 6.

The measured results of impurity contents, the maximum current efficiency and the time in which the luminance is damped to 80% of the samples are respectively shown below in table 3.

TABLE 3

| | | impurities in | | | maximum | luminance |
|---|---|---|---|---|---|---|
| | | polymer | | | current | damping |
| | chelating | (ppm) | | | efficiency | time |
| | agent | Na | Ni | Cl | (cd/A) | (time) |
| Sample 13 | EDTA/2NH₄ | 1 | 1 | 10 | 0.96 | 12 |
| Sample 14 | EDTA/2NH₄ | 10 | 10 | 45 | 0.65 | 1 |
| Sample 15 | EDTA/2Na | 20 | 5 | 40 | 0.55 | 2 |
| Sample 16 | EDTA/4Na | 30 | 10 | 40 | 0.22 | 0.5 |
| Sample 17 | EDTA/4Na | 60 | 20 | 285 | 0.09 | 0.5 |
| Sample 18 | — | 30 | 60 | 70 | 0.10 | 0.5 |

In the table 3, the maximum current efficiency indicates that a larger numeric value shows a higher light emitting efficiency like the table 1. In the samples 13 to 18, the maximum current efficiency was measured when voltage of 5.5 V was applied to the organic EL element. Further, as the luminance damping time, under a state that the current supplied to each sample was adjusted so that an initial luminance was 100 cd/m², the light emitting layer was continuously allowed to emit light and time until the luminance was 80 cd/m2 was measured. That is, the sample in which the time until the luminance is 80 cd/m² is shorter shows that the light emitting layer is deteriorated faster and the life of the organic EL element is shorter.

As shown in the table 3, it is found that in the samples 13 to 15 in which the chlorine content is 50 ppm or less and the sum total of the contents of sodium and nickel is less than the chlorine content, the maximum current efficiency is higher and the luminance damping time is longer than those of the samples 16 and 18 in which the sum total of the contents of sodium and nickel is not less than the chlorine content and the sample 17 having high chlorine content as much as 285 ppm.

In the samples 16 and 18, since the quantity of sodium and nickel as the impurities included in the poly (9,9-diethylhexyl) fluorene having a terminal end capped that forms the light emitting layer is large like the above-described sample 4, the light emitting efficiency is lowered or the polymer is deteriorated so that the maximum current efficiency is decreased and the luminance damping time is shortened.

In the sample 17, since the quantity of chlorine included in the poly (9,9-diethylhexyl) fluorene having a terminal end capped is too large like the above-described sample 5, the light emitting efficiency is lowered or the polymer is deteriorated so that the maximum current efficiency is decreased and the luminance damping time is shortened. Further, in the sample 17, since the metal content as the impurities is more than that of the samples 13 to 15, light emitting characteristics are more deteriorated.

Especially, in the samples 16 and 17, since EDTA/4Na is used as the chelating agent, a quantity of mixing of Na in the polymer is increased so that the light emitting characteristics are greatly deteriorated due to Na.

As compared with these samples, in the samples 13 to 15, since the quantity of the impurities such as chlorine or the metal elements included in the poly (9,9-diethylhexyl) fluorene having a terminal end capped is small like the above-described samples 1 to 3, the decrease of the light emitting efficiency or the deterioration of the polymer is suppressed so that the maximum current efficiency is increased and the luminance damping time is lengthened.

In the samples 13 to 18 using the poly (9,9-diethylhexyl) fluorene having a terminal end capped for the light emitting layer, since the light of different color from that of the samples 1 to 6 using the poly (9,9-dioctyl) fluorene for the light emitting layer is emitted, the maximum current efficiency is generally more increased due to the influence of the visibility. Specifically, the samples 13 to 18 using the poly (9,9-diethylhexyl) fluorene having a terminal end capped for the light emitting layer emit the light of blue.

As apparent from the above description, it is very important in producing the excellent organic EL element high in its maximum current efficiency and long in its luminance damping time to reduce the quantity of chlorine included in the poly (9,9-diethylhexyl) fluorene having a terminal end capped that forms the light emitting layer and more reduce the sum total of sodium and nickel included in the polymer than the quantity of chlorine that is set to a small value.

Subsequently, samples 19 to 24 obtained by actually forming the organic EL element using, as the electric transfer light emitting polymer, poly (9,9-diethylhexyl) fluorene having an end capped by di(p-tolyl)-4-bromophenyl amine that is synthesized by employing a palladium catalyst will be described below.

<Sample 19>

In a sample 19, as the electric transfer light emitting polymer included in the light emitting layer, poly (9,9-diethylhexyl) fluorene having a terminal end capped by di(p-tolyl)-4-bromophenyl amine was synthesized. When this polymer was synthesized, tetrakis (triphenyl phosphine) palladium (Pd(Ph₃)₄) of 150 mg (0.130 mmol) as a palladium catalyst, potassium carbonate of 10.1 g (73.0 mmol), tetrahydrofuran (THF) of 80 ml, distilled water of 40 ml, 2,7-dibromo9,9-diethylhexyl fluorene of 13.3 g (15.2 mmol), di(p-tolyl)-4-bromophenyl amine of 448 mg (1.28 mmol) and a compound having borons at a second position and a seventh position shown in a chemical formula 5 of 9.77 g (15.2 mmol) were mixed together, and the mixture was held at 60° C. and agitated. After 60 hours passed under the agitated state, concentrated 35% hydrochloric acid of 20 ml was added to the solution and the solution was quenched. In such a way, poly (9,9-diethylhexyl) fluorene having a terminal end capped by di(p-tolyl)-4-bromophenyl amine with high viscosity was synthesized.

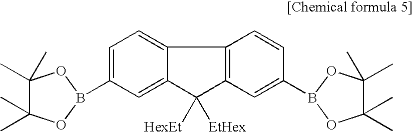

(In this case, EtHex represents below-described formula.)

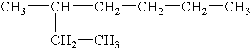

Then, in the sample 19, impurities in the polymer were removed in the same manner as that of the sample 1 for the poly (9,9-diethylhexyl) fluorene having a terminal end capped obtained by using the palladium catalyst as described above. Then, the organic EL element was produced in the same manner as that of the sample 1 except that the poly (9,9-diethylhexyl) fluorene having a terminal end capped in which the impurities in the polymer were removed in such a way was used.

<Sample 20>

In a sample 20, the organic EL element was produced in the same manner as that of the sample 2 except that the poly (9,9-diethylhexyl) fluorene having a terminal end capped synthesized by using the palladium catalyst was used as the electric transfer light emitting polymer.

<Sample 21>

In a sample 21, the organic EL element was produced in the same manner as that of the sample 3 except that the poly (9,9-diethylhexyl) fluorene having a terminal end capped synthesized by using the palladium catalyst was used as the electric transfer light emitting polymer.

<Sample 22>

In a sample 22, the organic EL element was produced in the same manner as that of the sample 4 except that the poly (9,9-diethylhexyl) fluorene having a terminal end capped synthesized by using the palladium catalyst was used as the electric transfer light emitting polymer.

<Sample 23>

In a sample 23, the organic EL element was produced in the same manner as that of the sample 5 except that the poly (9,9-diethylhexyl) fluorene having a terminal end capped synthesized by using the palladium catalyst was used as the electric transfer light emitting polymer.

<Sample 24>

In a sample 24, the organic EL element was produced in the same manner as that of the sample 6 except that the poly (9,9-diethylhexyl) fluorene having a terminal end capped synthesized by using the palladium catalyst was used as the electric transfer light emitting polymer.

The measured results of impurity contents and the maximum current efficiency of the samples are respectively shown below in table 4.

TABLE 4

| | | impurities in | | | maximum |
|---|---|---|---|---|---|
| | | polymer | | | current |
| | chelating | (ppm) | | | efficiency |
| | agent | Na | Ni | Cl | (cd/A) |
| Sample 19 | EDTA/2NH₄ | 1 | 1 | 20 | 0.88 |
| Sample 20 | EDTA/2NH₄ | 10 | 10 | 40 | 0.59 |
| Sample 21 | EDTA/2Na | 20 | 10 | 45 | 0.61 |
| Sample 22 | EDTA/4Na | 30 | 15 | 40 | 0.38 |
| Sample 23 | EDTA/4Na | 50 | 30 | 260 | 0.12 |
| Sample 24 | — | 30 | 50 | 70 | 0.24 |

In the samples 19 to 24, the maximum current efficiency was measured when voltage of 5.5 V was applied to the organic EL element.

As shown in the table 4, it is found that in the samples 19 to 21 in which the chlorine content is 50 ppm or less and the sum total of the contents of sodium and nickel is less than the chlorine content, the maximum current efficiency is higher than that of the samples 22 and 24 in which the sum total of the contents of sodium and nickel is not less than the chlorine content and the sample 23 having high chlorine content as much as 265 ppm.

In the samples 22 and 24, since the quantity of sodium and nickel as the impurities included in the poly (9,9-diethylhexyl) fluorene having a terminal end capped that forms the light emitting layer is large like the above-described sample 4, the light emitting efficiency is lowered or the polymer is deteriorated so that the maximum current efficiency is decreased.

In the sample 23, since the quantity of chlorine included in the poly (9,9-diethylhexyl) fluorene having a terminal end capped is too large like the above-described sample 5, the light emitting efficiency is lowered or the polymer is deteriorated so that the maximum current efficiency is decreased. Further, in the sample 23, since the metal content as the impurities is more than that of the samples 19 to 22, light emitting characteristics are more deteriorated.

Especially, in the samples 22 and 23, since EDTA/4Na is used as the chelating agent, a quantity of mixing of Na in the polymer is increased so that the light emitting characteristics are deteriorated due to Na.

As compared with these samples, in the samples 19 to 21, since the quantity of the impurities such as chlorine or the metal elements included in the poly (9,9-diethylhexyl) fluorene having a terminal end capped is small like the above-described samples 1 to 3, the decrease of the light emitting efficiency or the deterioration of the polymer is suppressed so that the maximum current efficiency is increased.

She samples 19 to 24 using the poly (9,9-diethylhexyl) fluorene having a terminal end capped that is prepared by palladium for the light emitting layer emit the light of blue.

As apparent from the above description, it is very important in producing the organic EL element excellent in its maximum current efficiency to reduce the quantity of chlorine included in the poly (9,9-diethylhexyl) fluorene having a terminal end capped that forms the light emitting layer and more reduce the sum total of sodium and palladium included in the polymer than the quantity of chlorine that is set to a small value.

It is to be understood to a person with ordinary skill in the art that the present invention is not limited to the above-described embodiment explained by referring to the drawing and various changes, substitutions or equivalence thereto may be made without departing from the attached claims and the gist thereof.

1. An electric transfer light emitting polymer that emits light by applying an electric field thereto, wherein chlorine (Cl) and the sum total (ΣM) of metal elements included in the polymer satisfy equation 1.
ΣM<Cl (1)
wherein ΣM designates the sum total of metal elements composed of one kind or a plurality of kinds of alkali metal elements, alkali earth metal elements, elements in the third period showing no anionic characteristics, elements in the fourth period showing no anionic characteristics and elements in the fifth period showing no anionic characteristics, and wherein the polymer comprises one or more units of a fluorene copolymer as shown in Chemical Formula 1, 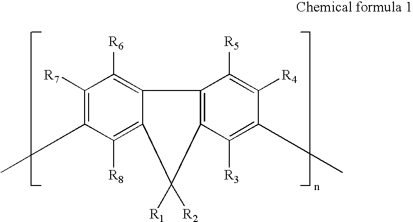
wherein n is an integer not smaller than 1, R₁ and R₂, each independently comprise at least one selected from a hydrogen atom, an alkyl group, an alkenyl group an alkynyl group, an aralkyl group, an aryl group, a hetero aryl group, an alkoxy group, an aryloxy group and an aliphatic heterocyclic group, and R₃ to R₈, are independently a hydrogen atom or an alkyl group.

2. The electric transfer light emitting polymer according to claim 1, wherein the chlorine content is 50 ppm or less.

3. The electric transfer light emitting polymer according to claim 2, wherein the metal elements are sodium, nickel and palladium.

4. (canceled)

5. An organic electroluminescence element having on a substrate a first electrode layer, a light emitting layer having an electric transfer light emitting polymer that emits light by applying an electric field thereto and a second electrode layer in this order, wherein in the light emitting layer, chlorine (Cl) and the sum total (ΣM) of metal elements included in the electric transfer light emitting polymer satisfy a relation of equation 2.
ΣM<Cl (2)
wherein ΣM designates the sum total of metal elements composed of one kind or a plurality of kinds of alkali metal elements, alkali earth metal elements, elements in the third period showing no anionic characteristics, elements in the fourth period showing no anionic characteristics and elements in the fifth period showing no anionic characteristics,
and wherein the polymer comprises one or more units of a fluorene copolymer as shown in Chemical Formula 1, 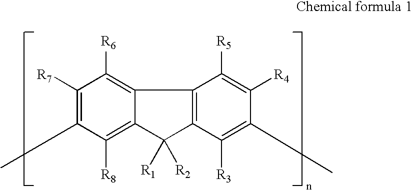
wherein n is an integer not smaller than 1, R₁ and R₂, each independently comprise at least one selected from a hydrogen atom, an alkyl group, an alkenyl group, an alkynyl group, an aralkyl group, an aryl group, a hetero aryl group, an alkoxy group, an aryloxy group and an aliphatic heterocyclic group, and R₃ to R₈ are independently a hydrogen atom or an alkyl group.

6. The organic electroluminescence element according to claim 5, wherein the chlorine content is 50 ppm or less.

7. The organic electroluminescence element according to claim 6, wherein the metal elements included in the light emitting layer are sodium, nickel and palladium.

8. (canceled)
